(19) United States
(12) Patent Application Publication
(10) Pub. No.: US 2024/0290410 A1
(43) Pub. Date: Aug. 29, 2024

(54) SEMICONDUCTOR MEMORY DEVICE WITH DYNAMICALLY VARYING SELF-REFRESH PERIOD

(71) Applicant: SAMSUNG ELECTRONICS CO., LTD., SUWON-SI (KR)

(72) Inventors: YOUNGJAE PARK, SUWON-SI (KR); SEUNGKI HONG, SUWON-SI (KR); DONGHA KIM, SUWON-SI (KR); HYUNBO KIM, SUWON-SI (KR)

(21) Appl. No.: 18/482,649

(22) Filed: Oct. 6, 2023

(30) Foreign Application Priority Data
Feb. 27, 2023 (KR) 10-2023-0026300

(51) Int. Cl. G11C 29/08

(52) U.S. Cl. CPC G11C 29/08

(57) ABSTRACT

Disclosed is a self-refresh method of a semiconductor memory device, including generating a temperature code indicative of a temperature of the semiconductor memory device; generating a first error flag indicative of any data errors in a memory area of the semiconductor memory device; performing a first self-refresh operation for the memory area within a first refresh period based on the temperature code and the first error flag; generating a second error flag indicative of any data errors in the memory area during the first self-refresh operation; and performing a second self-refresh operation for the memory area within a second refresh period based on the temperature code and the second error flag, wherein the second refresh period is longer than the first refresh period if the second error flag is indicative of no data errors in the memory area during the first self-refresh operation.

### CROSS-REFERENCE TO RELATED APPLICATIONS

This application claims priority under 35 U.S.C. § 119 to Korean Patent Application No. 10-2023-0026300, filed on Feb. 27, 2023 in the Korean Intellectual Property Office, the disclosure of which is incorporated by reference herein in its entirety.

### FIELD

The present disclosure relates to semiconductor memory devices, and more particularly relates to a semiconductor memory device having a dynamically varying self-refresh period, such as one responsive to temperature and error information, and a self-refresh method thereof.

### DISCUSSION

As a non-limiting example of a semiconductor memory device, a dynamic random-access memory (DRAM) device, which is considered to be one type of volatile memory, generally stores data by storing charges in corresponding capacitors. Since such charges stored in these capacitors may leak through various paths over time, DRAM has finite data retention characteristics.

DRAM generally uses a refresh operation to periodically rewrite data stored in the capacitors to extend data retention. DRAM refresh periods may be programmed in advance for each product in the manufacturing process. For example, a given DRAM may be set to perform a self-refresh operation at a specific period for a given temperature. A refresh period may be set shorter than the retention time so the DRAM can retain such data without unnecessary risk of data degradation, such as to provide an approximate margin of data reliability. Therefore, although there is generally a sufficient margin for the refresh period, such a DRAM may consume extra power due to such fixed refresh period settings.

### SUMMARY

An embodiment of the present disclosure provides a method for setting a refresh period of a semiconductor memory device based on retention characteristics while maintaining data reliability, such as by combining temperature codes and error information.

According to an embodiment, a self-refresh method of a semiconductor memory device includes generating a temperature code indicative of a temperature of the semiconductor memory device; generating a first error flag indicative of any data errors in a memory area of the semiconductor memory device; performing a first self-refresh operation for the memory area within a first refresh period based on the temperature code and the first error flag; generating a second error flag indicative of any data errors in the memory area during the first self-refresh operation; and performing a second self-refresh operation for the memory area within a second refresh period based on the temperature code and the second error flag, wherein the second refresh period is longer than the first refresh period if the second error flag is indicative of no data errors in the memory area during the first self-refresh operation.

According to an embodiment, a semiconductor memory device includes a cell array having a plurality of memory cells; an error correction circuit configured to generate an error flag during a self-refresh operation of the cell array; a temperature sensor configured to detect an operation temperature of the semiconductor memory device and generate a temperature code; a dynamic refresh period generator configured to generate a refresh period for the self-refresh operation by combining the temperature code and the error flag; and a refresh controller performing a self-refresh operation for the cell array according to the refresh period, wherein when the error flag is indicative of no data errors in the memory area during a first self-refresh operation, the dynamic refresh period generator is configured to generate an increased refresh period before a second self-refresh operation.

According to an embodiment, a self-refresh method of a semiconductor memory device includes generating a temperature code of the semiconductor memory device and a first error flag from a memory area to be refreshed; counting a number of occurrences of the first error flag; performing a first self-refresh operation for the memory area within a first refresh period based on the temperature code and the number of occurrences of the first error flag; generating a second error flag by detecting an error in the memory area during the first self-refresh operation; counting a number of occurrences of the second error flag; and performing a second self-refresh operation for the memory area with a second refresh period based on the temperature code and the number of occurrences of the second error flag, wherein when the number of occurrences of the second error flag is none, the second refresh period is longer than the first refresh period.

### BRIEF DESCRIPTION OF THE DRAWINGS

The above and other embodiments of the present disclosure will become more apparent by describing in detail illustrative embodiments thereof with reference to the accompanying drawings.

FIG. 1 is a block diagram illustrating a memory device according to an embodiment of the inventive concept.

FIG. 2 is a block diagram showing a configuration embodiment of the dynamic refresh period generator of FIG. 1.

FIG. 3 is a block diagram showing an embodiment of the code adder of FIG. 2.

FIG. 4 is a flowchart diagram illustrating an operation embodiment for generating a combinational code of the code adder of FIG. 3.

FIG. 5 is a block diagram showing a configuration embodiment of the refresh period generator of FIG. 2.

FIG. 6 is a timing diagram illustrating a method of changing a self-refresh period according to an embodiment of the inventive concept.

FIG. 7 is a block diagram showing an embodiment of the code adder of FIG. 2.

FIG. 8 is a tabular diagram showing an embodiment with addition codes ACODE based on the number of error flag occurrences generated by the code converter of FIG. 7.

FIG. 9 is a flowchart diagram illustrating an operation embodiment for generating combinational codes of the code adder of FIG. 7.

FIG. 10 is a timing diagram illustrating a method of changing a self-refresh period according to an embodiment of the inventive concept.

FIG. 11 is a schematic diagram of a memory module according to an embodiment of the inventive concept.

FIG. 12 is a cross-sectional diagram showing a memory system according to an embodiment of the inventive concept.

FIG. 13 is a block diagram illustrating a procedure embodiment for sharing a temperature code and/or an error flag in the memory system of FIG. 12.

FIG. 14 is a graphical diagram showing time versus temperature relationships for an embodiment of the inventive concept.

### DETAILED DESCRIPTION

It shall be understood that the inventive concept is disclosed by way of non-limiting illustrative examples in both the foregoing brief description as well as in the following detailed description. Illustrative embodiments of the inventive concept are indicated in the accompanying drawings, in which the same or like reference numbers may be used to refer to the same or like elements or parts, and substantially duplicate description may be omitted.

The data retention characteristics of various semiconductor memory devices may be related to environmental conditions, such as but not limited to an instantaneous current draw and/or operating temperature within each device. Moreover, the retention characteristics may also be related to cumulative characteristics of a given device. An optimized refresh period may be determined and dynamically varied in real-time based on current and somewhat cumulative conditions such as the driving temperature of the device and error information thereof, without limitation thereto.

Hereinafter, a dynamic random-access memory (DRAM) device will be used as an example of a semiconductor memory device for explaining illustrative embodiments of the present inventive concept, without limitation thereto. However, those skilled in the art will readily appreciate other embodiments of the present inventive concept in light of the teachings herein. For example, the present inventive concept may be implemented or applied through other embodiments, such as but not limited to those described herein and/or combinations thereof.

Moreover, the inventive concept may be applied to extend the data reliability of other memory types for varying environments and/or retention periods. In addition, the embodiments described herein may be modified or changed according to viewpoints and applications without significantly departing from the scope or spirit of the present inventive concept. In the description that follows, the terms ‘stamina’ and/or ‘strength’ may be used in referencing a retention ability or duration of time between refresh cycles that can be maintained without substantially losing data values stored in a DRAM cell due to charge degradation.

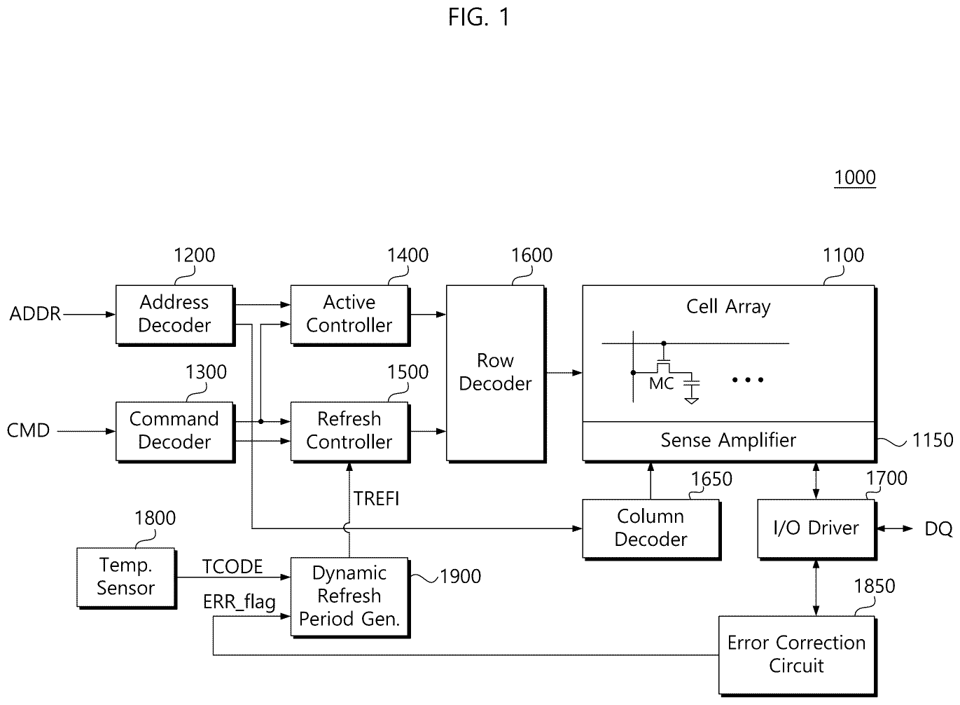

FIG. 1 illustrates a memory device according to an embodiment of the inventive concept. Referring to FIG. 1, a memory device 1000 includes a cell array 1100, a sense amplifier 1150, an address decoder 1200, a command decoder 1300, an active controller 1400, a refresh controller 1500, a row decoder 1600, a column decoder 1650, an input/output driver 1700, a temperature sensor 1800, an error correction circuit 1850, and a dynamic refresh period generator 1900.

The cell array 1100 includes a plurality of memory cells MC. Data stored in the memory cells MC may be read out to the input/output driver 1700 through the sense amplifier 1150. Similarly, write data received from the input/output driver 1700 may be stored in a selected memory cell MC through the sense amplifier 1150. For such read and write operations, the column decoder 1650 and the row decoder 1600 may select a memory cell corresponding to the address ADDR.

The address decoder 1200 receives an address ADDR of a memory cell to be accessed. When data is stored in the cell array 1100 or data is read from the cell array 1100, the address ADDR may be received and decoded by the address decoder 1200. The decoded address may be transmitted to the active controller 1400, the row decoder 1600, and the column decoder 1650. The row decoder 1600 and the column decoder 1650 may respectively select a row and column designated by the address ADDR.

The command decoder 1300 receives various commands, such as from an external host. The command decoder 1300 decodes and provides decoded commands to circuit blocks such as the active controller 1400, the refresh controller 1500, and the row decoder 1600. The command decoder 1300 may determine an input command by referring to externally applied control signals such as a Row Address Strobe (/RAS), a Column Address Strobe (/CAS), a Write Enable (/WE), and the like. Alternatively, the command decoder 1300 may write data into a mode register set (MRS), which may be included in the command decoder 1300, according to an externally provided command and address, without limitation thereto. For example, a general auto-refresh operation may be input through a combination of control signals such as /RAS, /CAS and/or /WE. Moreover, the refresh operation may be determined by the command decoder 1300, and the refresh command may be provided to the refresh controller 1500 by the mode register set MRS.

The active controller 1400 generates an active address and an active signal according to a write and/or read operation based on the address ADDR and command CMD as provided from the address decoder 1200 and the command decoder 1300, respectively, and provides the active address and the active signal to the row decoder 1600.

When an external refresh command is input to the memory device 1000, the refresh controller 1500 performs a refresh operation corresponding to the command. For example, when an all-bank refresh command is received, the refresh controller 1500 refreshes substantially all memory banks corresponding to the selected row. When a per-bank refresh command is received, the refresh controller 1500 performs a refresh operation on a bank selected from among a plurality of memory banks through a bank address.

Moreover, the refresh controller 1500 generates an internal address for refresh during a self-refresh operation and performs a refresh operation on memory cells selected by the internal address. During the self-refresh operation, the refresh controller 1500 performs a self-refresh cycle for the selected memory unit according to the refresh period TREFI provided from the dynamic refresh period generator 1900. Here, the refresh period TREFI may be characterized by data indicating a period of a self-refresh cycle, and/or may be a refresh clock signal having a refresh period TREFI.

The refresh period TREFI may be generated by referring to the temperature code TCODE, such as provided by the temperature sensor 1800, and the error flag ERR_flag, such as provided by the error correction circuit 1850. That is, the refresh period TREFI may vary according to the operating temperature of the memory device 1000 sensed in real time. In particular, the refresh period TREFI may be varied according to an error detected from a memory area to be refreshed.

According to an embodiment of the present inventive concept, the refresh period TREFI may continuously increase until an error (e.g., a correctable and/or uncorrectable data error) occurs. However, if it is determined that an error has occurred, the refresh period may be reduced compared to the previous self-refresh period or initialized to a default value, without limitation thereto. This may be described in greater detail with respect to the embodiments discussed below.

The row decoder 1600 controls the operation of the cell array 1100 based on the active address and active signal, provided from the active controller 1400, and further based on the refresh signal and refresh address, provided from the refresh controller 1500. During the self-refresh cycle, the row decoder 1600 activates the cell array row selected by the refresh controller 1500. The row decoder 1600 will activate the cell array row of the selected bank during the self-refresh cycle.

The input/output driver 1700 may receive data provided through the data pad DQ and provide the received data to the sense amplifier 1150. The input/output driver 1700 may output data stored in the cell array 1100 through the data pad DQ. In addition, the input/output driver 1700 may receive a data strobe signal DQS when receiving data. Moreover, when outputting data, the input/output driver 1700 may output the data using the data strobe signal DQS.

The temperature sensor 1800 may measure the temperature of the memory device 1000, and convert the measured temperature into a temperature code TCODE. The converted temperature code TCODE may be provided to the dynamic refresh period generator 1900. The temperature sensor 1800 may include a sensor circuit that senses the real-time temperature of the memory device 1000, and an analog-to-digital converter (ADC) that converts an analog temperature signal obtained from the sensor circuit into a digital code. A sensor circuit, which may be included in the semiconductor device 1000, may be generally implemented using bipolar junction transistors BJT, without limitation thereto. For example, the temperature signal may be obtained using a difference between two emitter-base voltages VEB, which may vary according to the ratio of the amount of current flowing through two bipolar junction transistors BJT. The analog temperature signal thus obtained may be converted into a temperature code TCODE by the analog-to-digital converter ADC. However, it shall be understood that the type of sensor circuit for sensing temperature is not limited to the above-described embodiment, and that various sensor elements may be used in or as a circuit for sensing temperature.

The error correction circuit 1850 detects errors in data and/or performs correction operations on the data. For example, the error correction circuit 1850 may generate error correction code (ECC) and/or parity data bits for input write data. ECC parity may be written to the parity field along with data in the cell array 1100. In addition, when outputting data, the error correction circuit 1850 may detect an error using ECC parity, without limitation thereto.

If an error that can be corrected is detected in the output data, the error correction circuit 1850 corrects the detected error bit and outputs an error flag ERR_flag. In particular, the error correction circuit 1850 performs error detection and correction on data read from a row selected during a self-refresh cycle. That is, the error correction circuit 1850 may perform error detection on data read during the self-refresh operation. When an error is detected, the error correction circuit 1850 may correct the detected error and output an error flag ERR_flag. In an embodiment, if an error that cannot be reliably corrected is detected in the output data, the error correction circuit 1850 may output the error flag ERR_flag more than once, and/or another signal such a severity or occurrence indicator.

The dynamic refresh period generator 1900 may generate a refresh period TREFI and/or a refresh clock signal based on a temperature code TCODE that varies according to temperature. In particular, the dynamic refresh period generator 1900 may adjust the refresh period TREFI by correlating the error flag ERR_flag with the temperature code TCODE. For example, the dynamic refresh period generator 1900 may repeatedly or continuously increase the refresh period TREFI when the error flag ERR_flag does not occur. If it is assumed that an error flag ERR_flag does not occur during a first refresh cycle for selected memory cells; then, in the second refresh cycle that follows, the dynamic refresh period generator 1900 may generate a period or refresh clock signal increased by a specific period increment (+β) from the refresh period TREFI applied in the first refresh cycle. On the other hand, if an error flag ERR_flag occurs in the first refresh cycle, the dynamic refresh period generator 1900 may generate in the second refresh cycle a period or refresh clock reduced by a specific period decrement (−β) from the refresh period TREFI applied in the first refresh cycle. Here, the size of the increased or decreased period offset (β) may be variously changed based on the value of the ERR_flag and/or the number of occurrences of the error flag ERR_flag.

In the above embodiment, an illustrative structure of the memory device 1000 has been described by way of example. The memory device 1000 of the present inventive concept may add or subtract a period adjustment of a specific size to a refresh period corresponding to the temperature code TCODE based on whether or not an error flag ERR_flag is generated. The self-refresh period of the memory device 1000 may continuously increase until an error occurs, for example. Accordingly, the self-refresh period of the memory device 1000 may converge to a refresh period value corresponding to retention characteristics or strength just less than one at which an error occurs.

Consequently, according to this embodiment of the present inventive concept, it is possible to set a refresh period that can maximize the retention characteristics of memory cells and/or minimize power consumption. According to the technique of this embodiment, the refresh period of the memory device 1000 may be set to a value that may substantially optimize and/or guarantee reliability without wasting energy. This makes it possible to minimize the current consumption caused by repeated executions of the self-refresh operation.

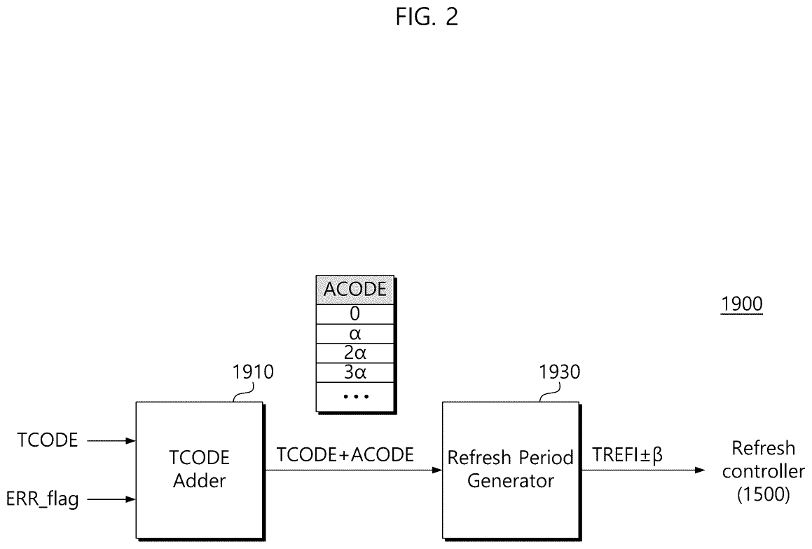

FIG. 2 shows the configuration of the dynamic refresh period generator of FIG. 1. Referring to FIG. 2, a dynamic refresh period generator 1900 includes a code adder 1910 and a refresh period generator 1930.

The code adder 1910 may add the temperature code TCODE and the addition code ACODE corresponding to the error flag ERR_flag. That is, the code adder 1910 may generate a combination code (TCODE+ACODE) correlating the effect of the error flag ERR_flag on the temperature code TCODE. For example, if the error flag ERR_flag did not occur during the previous self-refresh cycle for the selected memory area, the code adder 1910 adds a code value ‘α’ of the addition code ACODE greater than zero (‘0’) to the temperature code TCODE to be applied in the next self-refresh cycle. On the other hand, when an error flag ERR_flag occurs during the previous self-refresh cycle for the selected memory area, the code adder 1910 generates a combination code (TCODE+ACODE) by subtracting the code value ‘α’ of the addition code ACODE applied in the previous self-refresh cycle from the temperature code TCODE to be applied in the next self-refresh cycle.

The method of generating the combination code (TCODE+ACODE) may be described in greater detail as follows. Assume that the error flag ERR_flag has not occurred until the ‘N−1’th refresh cycle, and The code value of the addition code ACODE added to the temperature code TCODE may be ‘4α’. In the subsequent ‘N’th refresh cycle, the code value of the addition code ACODE added to the temperature code TCODE becomes ‘5α’. However, assume that an error flag ERR_flag occurs during the progress of the ‘N’th refresh cycle. In the ‘N+1’th refresh cycle, the code value of the addition code ACODE added to the temperature code TCODE becomes ‘4α’ obtained by subtracting ‘α’. And, in the ‘N+1’th refresh cycle, a self-refresh period will be generated based on the combination code ‘TCODE+4α’.

The refresh period generator 1930 generates a self-refresh period using the combination code (TCODE+ACODE) output from the code adder 1910. That is, the refresh period generator 1930 may add or subtract the period ‘β’, corresponding to the addition code ACODE, to the self-refresh period TREFI for the selected memory area. The self-refresh period ‘TREFI+β’ or ‘TREFI-β’, generated by the refresh period generator 1930, is provided to the refresh controller 1500. The self-refresh period ‘TREFI+β’ or ‘TREFI-β’ may be used by the refresh controller 1500 as data for generating self-refresh pulses.

As described above, the dynamic refresh period generator 1900 may dynamically vary the self-refresh period, such as by correlating the influence of the error flag ERR_flag and the temperature code TCODE. According to the present inventive concept, the self-refresh period can be extended as long as the error flag ERR_flag does not occur or until a correctable error occurs. Accordingly, it is possible to set a self-refresh period capable of maximally utilizing the retention characteristics of the memory cell. This can drastically reduce the current consumption of the memory device 1000 according to the self-refresh operation.

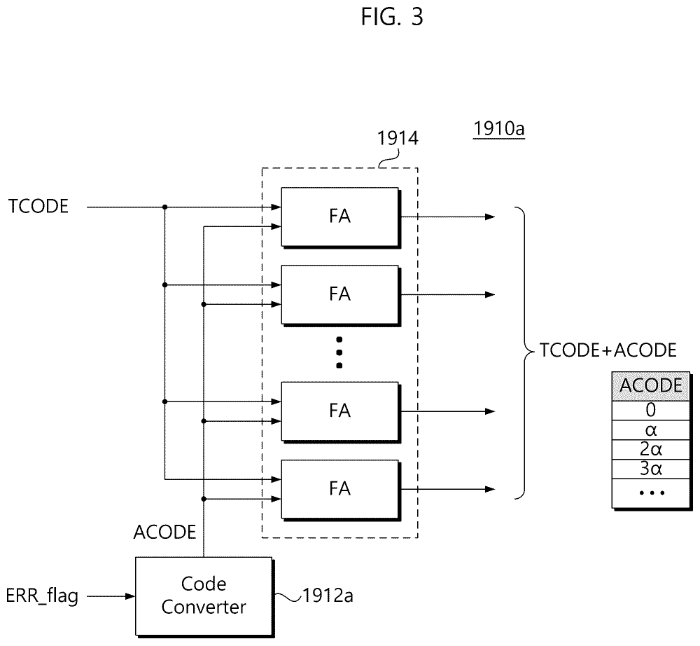

FIG. 3 shows an embodiment of the code adder of FIG. 2. Referring to FIG. 3, a code adder 1910a may include a code converter 1912a and a plurality of full adders 1914 to combine the temperature code TCODE and the error flag ERR_flag.

The code converter 1912a generates an addition code ACODE that may be added to the temperature code TCODE according to whether an error flag ERR_flag is generated. For example, assuming an m-bit temperature code TCODE, the code converter 1912a may generate an addition code ACODE of m-bits or less. The size of the code values (e.g., 0, α, 2α, . . . ) of the addition code ACODE may be determined according to the increasing or decreasing self-refresh period β.

If the error flag ERR_flag does not occur during one self-refresh cycle previously performed, the code converter 1912a generates an addition code of the code value ‘α’ to increase the period in the next self-refresh cycle. The code value ‘α’ of the generated addition code ACODE may be stored in a register inside the code converter 1912. If the error flag ERR_flag does not occur even in the current self-refresh cycle, the code converter 1912a generate a code value ‘2α’ to be applied to the next self-refresh cycle referring to the code value α of the addition code ACODE in the current cycle stored in the internal register. Thus, the refresh period in the next self-refresh cycle may be additionally increased.

On the other hand, if the error flag ERR_flag occurs at least once during one previously performed self-refresh cycle, the code converter 1912a subtracts the code value ‘α’ from the code value of the previously applied addition code ACODE. According to the subtraction of the code value ‘α’, the period of the current self-refresh cycle may be reduced compared to the previous self-refresh cycle.

An illustrative configuration of the code adder 1910a has been described above. However, the present inventive concept is not limited to the disclosure herein. A means for combining the temperature code TCODE and the error flag ERR_flag to increase or decrease the self-refresh period with reference to the error flag ERR_flag may be implemented in various ways.

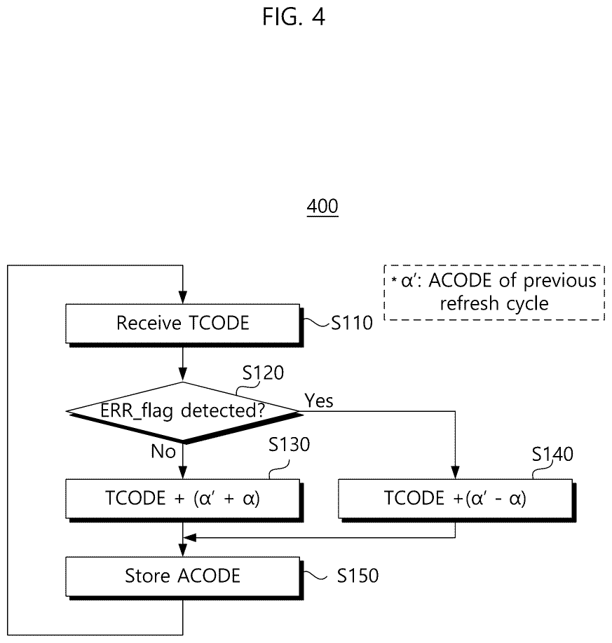

FIG. 4 illustrates an operation 400 of generating a combinational code of the code adder of FIG. 3. Referring to FIG. 4, a code adder 1910a (see FIG. 3) generates a combination code TCODE+ACODE for setting a self-refresh period from a temperature code TCODE and an error flag ERR_flag.
In step S110, the code adder 1910a receives the temperature code TCODE. The temperature code TCODE may be a code value detected in real time by the temperature sensor 1800 (see FIG. 1) described above and converted into a digital signal. Each bit of the temperature code TCODE may be input to the plurality of full adders 1914 (see FIG. 3) in units of bits.
In step S120, the code converter 1912 (see FIG. 3) detects whether an error flag ERR_flag has occurred. The error flag ERR_flag may occur when an error of refreshed data is detected and corrected by the error correction circuit 1850 (refer to FIG. 1). Accordingly, the code converter 1912a can detect whether the low level error flag ERR_flag transitions to a high level. The error flag ERR_flag may be detected when the self-refresh period for the selected memory area is completed. If the error flag ERR_flag does not occur (‘No’ direction), the procedure moves to step S130. On the other hand, when an error flag ERR_flag occurs (‘Yes’ direction), the procedure moves to step S140.
In step S130, the code converter 1912a generates a code value α for increasing the refresh period. That is, the code converter 1912a generates an addition code (α′+α) for increasing a specific cycle (e.g., β) rather than a self-refresh period generated by the temperature code TCODE. Here, the code value (α′) may be a code value added to the temperature code TCODE in the previous self-refresh cycle, and may be a value stored in an internal register of the code converter 1912. Thus, the plurality of full adders 1914 may calculate and output a combination code by adding an addition code (α′+α) to the temperature code TCODE provided in real time.
In step S140, the code converter 1912a generates a code value (α′−α) for decreasing the refresh period. Here, the code value (α′) may be an addition code ACODE added to the temperature code TCODE in the previous self-refresh cycle. For example, the addition code ACODE becomes (α+α+α=3α) when no error code has occurred three consecutive times in the previous self-refresh cycles. Accordingly, the code converter 1912a will generate an addition code ACODE of (2α) reduced by the code value (α) compared to the previous cycle in the current self-refresh cycle.

In an embodiment, it may be assumed that the code converter 1912a adds an error code value of (5α) to the temperature code TCODE in the previous self-refresh cycle, and an error flag ERR_flag may be generated due to a corresponding increase in the refresh period. Thus, the code converter 1912a may generate in the current self-refresh cycle an addition code ACODE of (4α) subtracted by (α) from the addition code (5α) added in the previous cycle. The plurality of full adders 1914 may add the code value (α′−α) to the temperature code TCODE provided in real time and output the combined code.
In step S150, the code converter 1912a stores the addition code ACODE generated in step S130 or step S140 in an internal register. That is, the addition code ACODE so stored may be provided as the addition code α′ of the previous cycle in the next self-refresh cycle. Thereafter, the procedure returns to step S110.

In the above, the method of combining the temperature code TCODE and the error flag ERR_flag of the code adder 1910a has been briefly described. As a result, when the error flag ERR_flag does not occur, the code adder 1910a performs an operation of increasing the refresh period as the refresh cycle increases. On the other hand, when an error flag ERR_flag occurs, the code adder 1910a subtracts the code value α from the code value α′ of the addition code ACODE applied in the previous refresh cycle. Therefore, the self-refresh period may be reduced from that of the previous refresh cycle.

Although the above-described embodiment adjusts a temperature code based on addition or effective subtraction of an addition code, embodiments are not limited thereto. For example, the dynamic refresh period generator may provide a refresh period signal to the refresh controller that is a complex function of the TCODE and the ACODE, without limitation thereto.

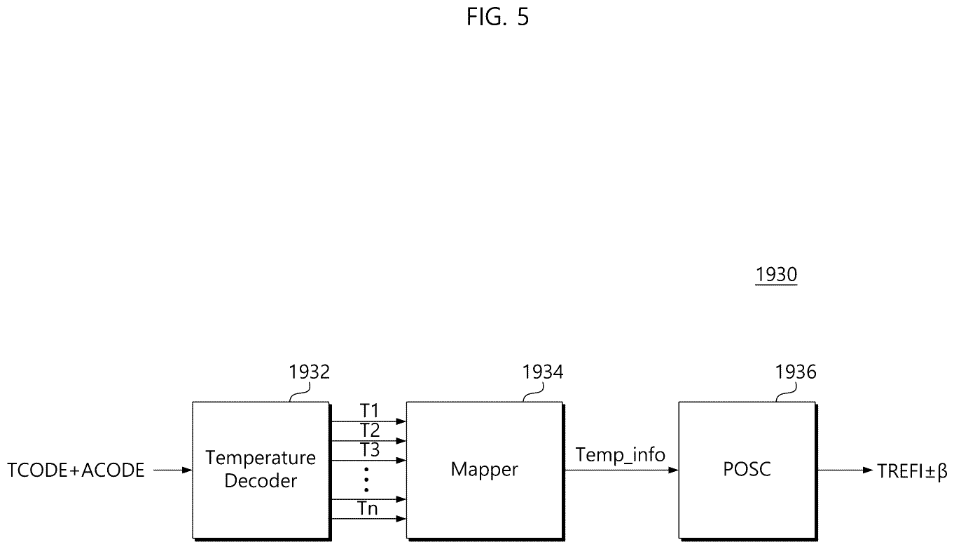

FIG. 5 shows the configuration of the refresh period generator of FIG. 2. Referring to FIG. 5, a refresh period generator 1930 may include a temperature decoder 1932, a mapper 1934, and an oscillator 1936.

The temperature decoder 1932 receives the combination code TCODE+ACODE and outputs corresponding temperature level information (Tj, 1≤j≤n). The temperature decoder 1932 may be a component that generates temperature level information Tj corresponding to an input temperature code TCODE. However, in the present inventive concept, a combination code TCODE+ACODE may be input to the temperature decoder 1932 instead of the temperature code TCODE. Accordingly, the temperature decoder 1932 may output the temperature level information Tj by correlating the addition code ACODE to the temperature code TCODE.

For example, assuming that the temperature code TCODE, corresponding to 50° C., and the addition code ACODE, by the error flag ERR_flag, are added to the combination code TCODE+α; then the temperature level information Tj may generate ‘T55’ of an increased level instead of ‘T50’ corresponding to 50° C. That is, when an error flag ERR_flag is generated and the addition code ACODE is added, the temperature decoder 1932 outputs temperature level information Tj corresponding to a temperature higher than the current device temperature.

The mapper 1934 generates temperature information Temp_info corresponding to the temperature level information Tj. The mapper 1934 may have temperature information Temp_info mapped on a one-to-one basis to the temperature level information Tj of various levels. That is, the mapper 1934 may store temperature information Temp_info corresponding to the temperature level information Tj in the form of a table. When the temperature level information Tj is input, the mapper 1934 provides, to the oscillator 1936, temperature information Temp_info mapped thereto.

The oscillator 1936 generates a refresh clock TREFI or a refresh period based on the temperature information Temp_info. Based on the refresh clock TREFI, the refresh controller 1500 drives an address counter designating a row address for self-refresh. As a result, the period of the refresh clock TREFI may be varied by a combination code TCODE+ACODE in which both the temperature code TCODE and the error flag ERR_flag are reflected. And, if an error does not occur, the period continuously increases as the self-refresh cycle is repeated. On the other hand, in the next self-refresh period at the time when the error flag occurred, the period of the previous cycle will be restored.

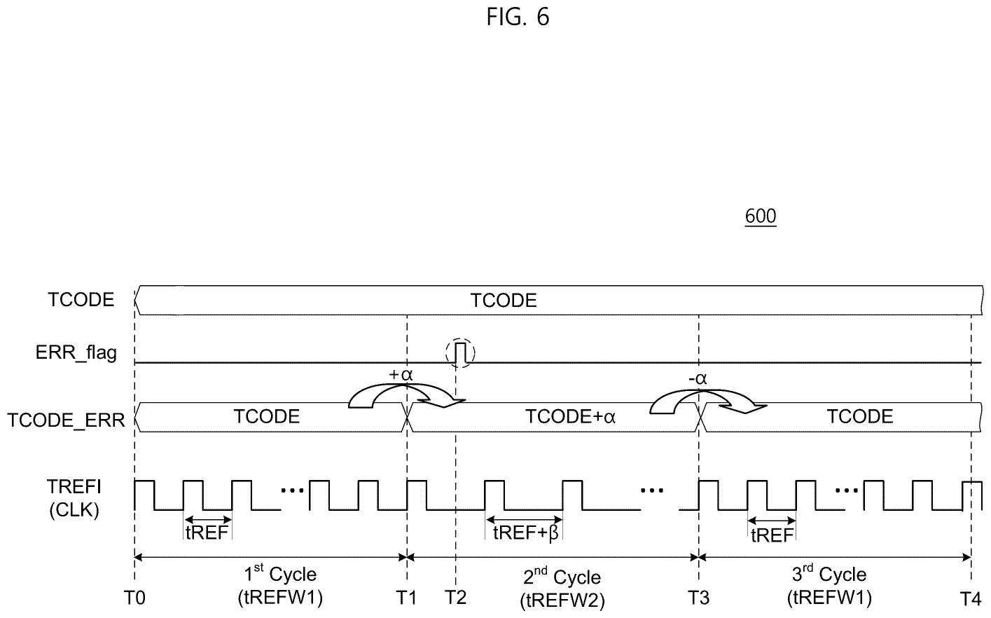

FIG. 6 illustrates signal timing 600 for a method of changing a self-refresh period according to an embodiment of the present inventive concept. Referring to FIG. 6, the period of the refresh clock TREFI may be increased or decreased according to whether the error flag ERR_flag is generated. Hereinafter, it will be assumed that the temperature code TCODE provided by the temperature sensor 1800 (see FIG. 1) maintains a constant value. However, in a real environment, the value of the temperature code TCODE may also fluctuate depending on the temperature.
At time T0, the first cycle (1st Cycle) of the self-refresh operation may be performed. One refresh cycle corresponds to the time (e.g., tREFW1) used to select and refresh substantially all rows of the selected memory unit. It may be assumed that the period of the refresh clock TREFI in the first cycle is ‘tREF’. Then, pulses as many as the number of rows (e.g., 8K) are generated to complete self-refresh for the memory unit selected in the first cycle. Accordingly, the time used to complete the first self-refresh cycle may be ‘tREFW1’, which is a value that may be obtained by multiplying the refresh clock cycle ‘tREF’ by the number of rows.
At time T1, the second cycle of self-refresh begins. In the first cycle, the error flag ERR_flag did not occur. Accordingly, in the second cycle, the combination code TCODE+ACODE may be generated as ‘TCODE+α’ obtained by adding the addition code ACODE to the temperature code TCODE. And, by the addition of the addition code ACODE, the period of the refresh clock TREFI in the second cycle may be ‘tREF+β’. As a result, in the second cycle, the time used to complete the first self-refresh cycle becomes ‘tREFW2(>tREFW1)’.
At time T3, the third cycle of self-refresh starts. However, an error flag ERR_flag occurred during the second cycle (at time T2). Accordingly, the combination code TCODE+ACODE in the third cycle may be generated as ‘TCODE’ obtained by subtracting the addition code ACODE (=α) from the temperature code TCODE of the second cycle. By subtracting the addition code ACODE, the period of the refresh clock TREFI in the third cycle can be restored to the same ‘tREF’ as in the first cycle. As a result, in the third cycle, the time used to complete the third cycle can be reduced to ‘tREFW1’.

According to the above description, as the error flag ERR_flag is applied to the temperature code TCODE, the self-refresh period may increase to the limit of retention performance of the memory cell. Accordingly, the self-refresh period may be increased to the maximum extent to which data reliability of the memory device 1000 is guaranteed. This may contribute to minimizing current consumption generated by the self-refresh operation of the memory device 1000.

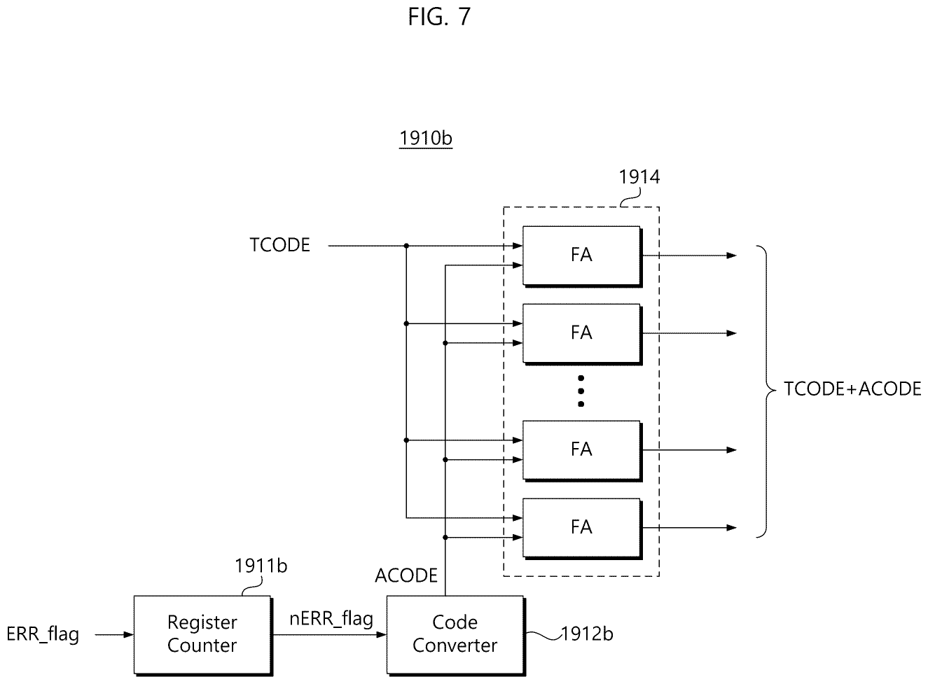

FIG. 7 shows an embodiment of the code adder of FIG. 2 according to the present inventive concept. Referring to FIG. 7, a code adder 1910b according to an embodiment may include a register counter 1911, a code converter 1912b, and a plurality of full adders 1914. Since the plurality of full adders 1914 are substantially the same as those of FIG. 3, duplicate description thereof may be omitted.

The register counter 1911b may count the number of occurrences nERR_flag of the error flag ERR_flag. For example, the register counter 1911b may count the number of error flags ERR_flag generated during one self-refresh cycle. Alternatively, the register counter 1911b may count the number of error flags ERR_flag generated over the self-refresh cycles of substantially the entire memory device 1000. The register counter 1911b may generate the number of occurrences of the error flag nERR_flag and provide it to the code converter 1912b.

The code converter 1912b generates an addition code ACODE added to the temperature code TCODE according to the number of occurrences of the error flag nERR_flag. For example, the code converter 1912b may generate an a relatively large addition code value (e.g., α′+α, where α′ is the ACODE contribution of the previous refresh cycle and α is the ACODE contribution of present refresh cycle), when the number of occurrences of the error flag nERR_flag is substantially zero (‘0’). On the other hand, the code converter 1912b may generate a relatively medium addition code value (e.g., α′−α/2) when the number of occurrences of the error flag nERR_flag is about ‘1’. Moreover, when the number of occurrences of the error flag nERR_flag is about ‘2’, the code converter 1912b may generate a relatively small addition code value (e.g., α′−α) by subtracting an amount from the code value added in the previous cycle. In addition, when the number of occurrences of the error flag nERR_flag is about ‘3’ or more, the code converter 1912b may generate a substantially zero addition code value (e.g., ‘0’).

In the above-described embodiment, period variation values of various sizes may be provided for various refresh periods according to the number of occurrences nERR_flag of the error flag ERR_flag, or the like.

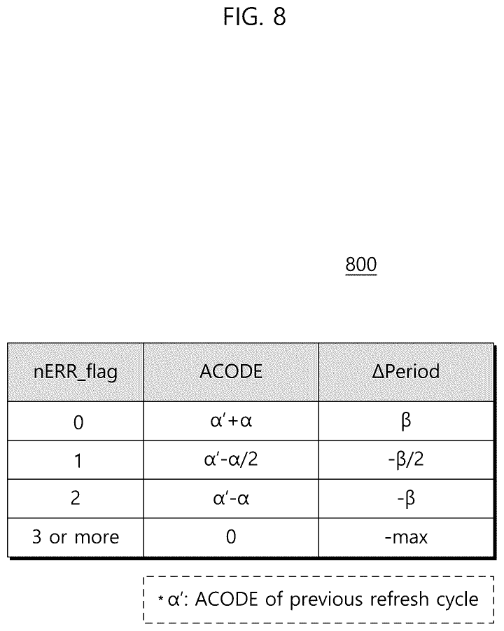

FIG. 8 shows a table 800 with addition codes ACODE according to the number of error flag occurrences nERR_flag generated by the code converter of FIG. 7. Referring to FIG. 8, the code converter 1912b may generate an addition code ACODE whose size may be variable according to the number of occurrences of the error flag nERR_flag.

When the number of error flag occurrences nERR_flag input to the code converter 1912b is ‘0’, an addition code value (α′+α) may be generated. Here, (α′) corresponds to the addition code ACODE generated in the previous self-refresh cycle stored in the internal register of the code converter 1912. That is, when there is no history of occurrence of an error flag up to the previous self-refresh cycle, the code converter 1912b may generate (α). This corresponds to an addition code ACODE capable of increasing the period of the refresh clock TREFI by ‘β’ more than the period of the previous self-refresh cycle.

When the detected error flag occurrence count nERR_flag is ‘1’, the code converter 1912b generates an addition code value (α′−α/2). That is, if it is determined that the error flag occurred or increased once in the previous self-refresh cycle, the code converter 1912b subtracts (α/2) from the addition code value (α′) generated in the previous self-refresh cycle. This corresponds to an addition code ACODE capable of reducing the period of the refresh clock TREFI by ‘β/2’ compared to the period of the previous self-refresh cycle.

When the number of occurrences of the error flag nERR_flag is ‘2’, the code converter 1912b generates an addition code value (α′−α). That is, if it is determined that the error flag has occurred twice in the previous self-refresh period, the code converter 1912b obtains an additional code value obtained by subtracting (α) from the additional code value (α′) generated in the previous self-refresh period. This corresponds to an addition code ACODE capable of reducing the period of the refresh clock TREFI by ‘β’ more than the period of the previous self-refresh cycle.

Also, when the number of occurrences of the error flag nERR_flag is ‘3’ or more, the code converter 1912b generates an addition code value of ‘0’. That is, if it is determined that the error flag has occurred three or more times (including uncorrectable errors) in the previous self-refresh cycle, the code converter 1912b may generate an addition code ACODE ‘0’. This corresponds to an addition code ACODE that generates the period of the refresh clock TREFI purely dependent on the temperature code TCODE. That is, it corresponds to a measure of maximally reducing the refresh period.

The configuration of the above table is to explain an example in which the self-refresh period can be adjusted to various values according to the number of occurrences of the error flag. The size of the addition code ACODE can be replaced with various values, and the present inventive concept is not limited to the particular illustrative details of figures shown.

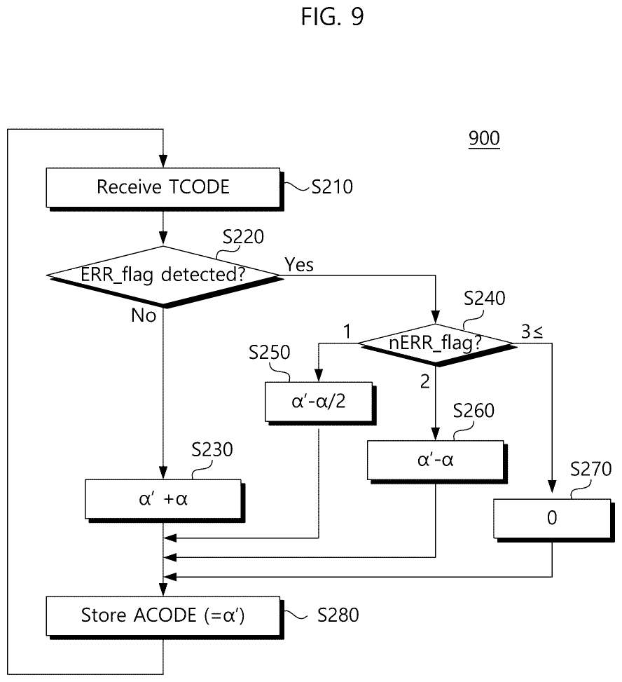

FIG. 9 illustrates an operation 900 of generating combinational codes of the code adder of FIG. 7. Referring to FIG. 7 and FIG. 9, the code adder 1910b generates a combination code TCODE+ACODE for setting a self-refresh period from a temperature code TCODE and an error flag ERR_flag.
In step S210, the code adder 1910b receives the temperature code TCODE. The temperature code TCODE may be a code value detected in real time by the temperature sensor 1800 of FIG. 1 as described above, and converted into a digital signal. Each bit of the temperature code TCODE may be input to the plurality of full adders 1914 in units of bits.
In step S220, the code converter 1912b detects whether an error flag ERR_flag has occurred. The error flag ERR_flag may be generated when the error correction circuit 1850 detects and corrects an error in refreshed data. Accordingly, the code converter 1912b can detect whether the low level error flag ERR_flag transitions to a high level. The error flag ERR_flag may be detected when the self-refresh cycle for the selected memory area is completed. If the error flag ERR_flag does not occur (‘No’ direction), the procedure moves to step S230. On the other hand, if an error flag ERR_flag has occurred (‘Yes’ direction), the procedure moves to step S240.
In step S230, the code converter 1912b generates an addition code ACODE for increasing the refresh period. That is, the code converter 1912b generates an additional code value (α′+α) for increasing a specific period (e.g., β) from the self-refresh period generated by the temperature code TCODE. Here, (α′) corresponds to an addition code value generated in the previous self-refresh cycle stored in an internal register of the code converter 1912. The plurality of full adders 1914 calculate and output a combination code (TCODE+α′+α) by adding the addition code ACODE to the temperature code TCODE provided in real time.
In step S240, the code converter 1912b detects the number of occurrences of an error flag nERR_flag. If the number of occurrences of the error flag nERR_flag is ‘1’, the procedure moves to step S250. If the number of occurrences of the error flag nERR_flag is ‘2’, the procedure moves to step S260. And, if the number of error flag occurrences nERR_flag is ‘3’ or more (including uncorrectable errors), the procedure moves to step S270.
In step S250, when the number of occurrences of the error flag nERR_flag is ‘1’, the code converter 1912b generates an addition code value (α′−α/2). That is, if it is determined that the error flag occurred once in the previous self-refresh cycle, the code converter 1912b subtracts (α/2) from the addition code value (α′) generated in the previous self-refresh cycle to generates a code value (α′−α/2). This corresponds to an addition code ACODE capable of reducing the period of the refresh clock TREFI by ‘β/2’ compared to the period of the previous self-refresh cycle.
In step S260, when the number of occurrences of the error flag nERR_flag is ‘2’, the code converter 1912b generates an addition code value (α′−α). That is, if it is determined that the error flag has occurred twice in the previous self-refresh cycle, the code converter 1912b obtains an additional code value obtained by subtracting (α) from the additional code value (α′) generated in the previous self-refresh cycle. This corresponds to an addition code ACODE capable of reducing the period of the refresh clock TREFI by ‘β’ more than the period of the previous self-refresh cycle.
In step S270, if the number of occurrences of the error flag nERR_flag is ‘3’ or more, the code converter 1912b generates an addition code value of ‘0’. That is, if it is determined that the error flag has occurred three or more times (including uncorrectable errors) in the previous self-refresh period, the code converter 1912b may generate an addition code ACODE ‘0’. This corresponds to an addition code ACODE that generates the cycle of the refresh clock TREFI purely dependent on the temperature code TCODE. That is, the addition code ACODE ‘0’ may be a measure of maximally reducing the refresh period.
In step S280, the code converter 1912b stores the addition code ACODE generated in at least one of steps S230, S250, S260, and S270 in an internal register. That is, the addition code ACODE stored at this time may be provided as the addition code (α′) of the previous cycle in the next self-refresh cycle. Thereafter, the procedure returns to step S210.

In the above, the method of combining the temperature code TCODE of the code adder 1910b and the number of occurrences of the error flag nERR_flag has been briefly described, without limitation thereto. The code adder 1910b may dynamically adjust the self-refresh period according to the number of error flag occurrences nERR_flag.

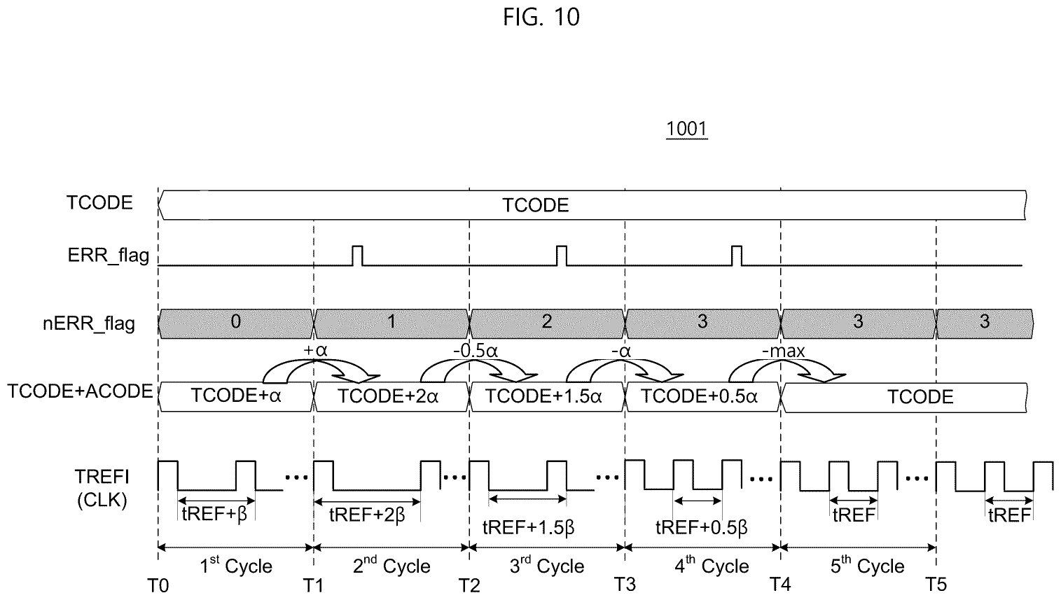

FIG. 10 illustrates signal timing 1001 for a method of changing a self-refresh period according to an embodiment of the present inventive concept. Referring to FIG. 10, the period of the refresh clock TREFI may be increased or decreased according to the number of occurrences of the error flag nERR_flag. Hereinafter, it will be assumed that the temperature code TCODE provided by the temperature sensor 1800 (see FIG. 1) maintains a constant value.
At time T0, the first cycle (1st Cycle) of the self-refresh operation may be performed. One refresh cycle corresponds to a period in which substantially all rows of the selected memory unit are selected and refreshed. If it is assumed that the number of occurrences of the error flag nERR_flag up to the first cycle is ‘0’, then the code adder 1910b outputs the code value of the combined code TCODE+ACODE as ‘TCODE+α’. According to the code value of the combination code TCODE+ACODE, the period of the refresh clock TREFI in the first cycle may be set to ‘tREF+β’.
At time T1, the second cycle of self-refresh starts. The error flag ERR_flag did not occur until the first cycle. Therefore, in the second cycle, the combination code TCODE+ACODE may be generated as ‘TCODE+2α’, which is increased by the addition code value ‘α’ compared to the first cycle. In the second cycle, the period of the refresh clock TREFI may be ‘tREF+2β’.

At the time point T2, the 3rd cycle of self-refresh starts. However, the error flag ERR_flag occurred once during the second cycle. Accordingly, the number of occurrences of the error flag nERR_flag until the second cycle corresponds to ‘1’. In the third cycle, the combination code TCODE+ACODE may be generated as ‘TCODE+1.5α’ subtracted by ‘-0.5α’ from the combination code value ‘TCODE+2α’ in the second cycle. By subtraction of the addition code ACODE, the period of the refresh clock TREFI in the third cycle may be ‘tREF+1.5β’.
At time T3, the fourth cycle of self-refresh starts. However, an error flag ERR_flag was additionally generated during the third cycle. Accordingly, the number of occurrences of the error flag nERR_flag up to the third cycle corresponds to ‘2’. In the fourth cycle, the combination code TCODE+ACODE may be generated as ‘TCODE+0.5α’ subtracted by ‘-α’ from the combination code value TCODE+1.5α in the third cycle. By subtraction of the addition code ACODE, the period of the refresh clock TREFI in the fourth cycle becomes ‘tREF+0.5β’.
At time T4, the fifth cycle of self-refresh starts. However, an error flag ERR_flag was additionally generated during the fourth cycle. Accordingly, the number of occurrences of the error flag nERR_flag up to the fourth cycle corresponds to ‘3’. In the fifth cycle, the combination code TCODE+ACODE may be subtracted ‘max’ code from the combination code value TCODE+0.5α in the fourth cycle, except for the temperature code TCODE component. Accordingly, in the fifth cycle, the combination code TCODE+ACODE may be generated as ‘TCODE’. By subtraction of the addition code ACODE, the period of the refresh clock TREFI in the fifth cycle becomes ‘tREF’.

In the refresh cycles after the time T5, the number of occurrences of the error flag nERR_flag will be maintained at ‘3’ or more. Accordingly, the period of the refresh clock TREFI after the fifth cycle may be maintained as ‘tREF’.

According to the above description, as the error flag ERR_flag is applied to the temperature code TCODE, the self-refresh period may increase to the limit of retention characteristics of the memory cell. Accordingly, the self-refresh period may be increased to the maximum extent to which data reliability of the memory device 1000 is guaranteed. This may contribute to minimizing current consumption generated by the self-refresh operation of the memory device 1000.

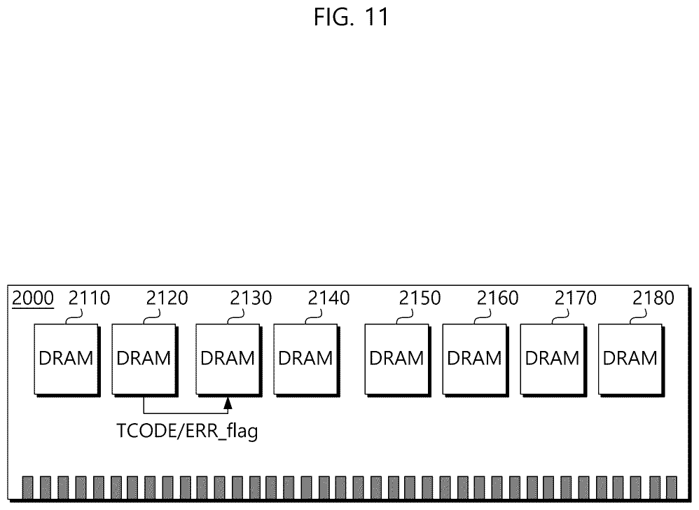

FIG. 11 shows a memory module 2000 according to an embodiment of the present inventive concept. Referring to FIG. 11, a memory module includes a plurality of memory devices 2110 to 2180. Moreover, the temperature code TCODE or error flag ERR_flag in one memory device 2120 may be provided to the other memory device 2130.

When there is a failure or error in the temperature sensor or related circuit of the memory device 2130, the memory device 2130 cannot generate a compensated self-refresh period. In this case, a temperature code TCODE or an error flag ERR_flag may be provided from an adjacent memory device 2120 having characteristics similar to those of the memory device 2130. To this end, a channel capable of sharing a temperature code TCODE or an error flag ERR_flag may be separately provided in each of the plurality of memory devices 2110 to 2180. Thus, the memory device 2120 capable of normally generating the temperature code TCODE or error flag ERR_flag may transfer the generated temperature code TCODE or error flag ERR_flag to the memory device 2130 through this channel.

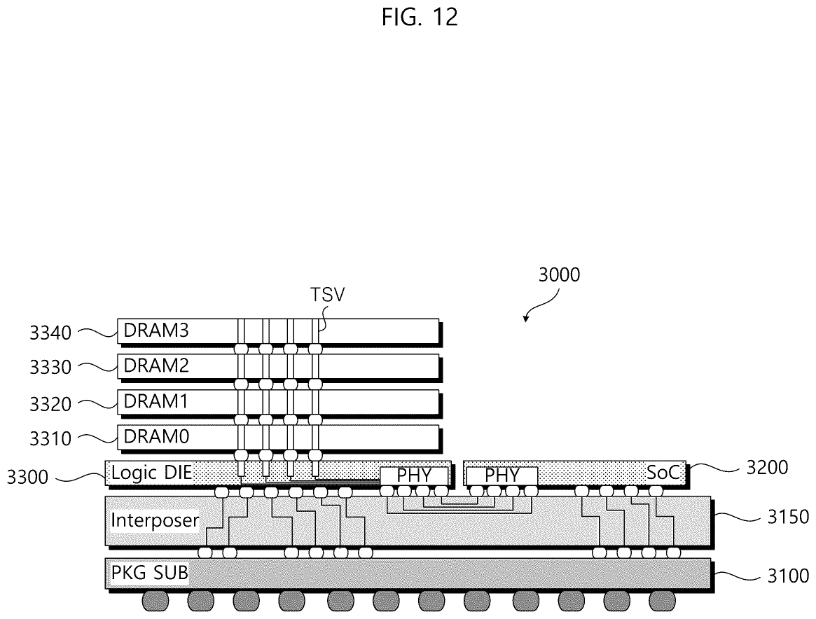

FIG. 12 shows a memory system according to an illustrative embodiment of the inventive concept. Referring to FIG. 12, a memory system 3000 implemented as a stacked memory includes a printed circuit board (PCB) substrate 3100, an interposer 3150, a host die 3200, a logic die 3300, and high-bandwidth DRAMs 3310, 3320, 3330, 3340.

The memory system 3000 connects the high-bandwidth DRAMs 3310, 3320, 3330, and 3340 and the host die 3200 using the interposer 3150. The interposer 3150 may be disposed on the PCB 3100 and may be electrically connected to the PCB 3100 through flip chip bumps FB.

A host die 3200, a logic die 3300, and high-bandwidth DRAMs 3310, 3320, 3330 and 3340 are configured in a stacked structure and may be disposed on the interposer 3150. To implement the memory system 3000, through-silicon via (TSV) lines are formed in the plurality of high-bandwidth DRAMs 3310, 3320, 3330, and 3340. The TSV lines may be electrically connected to micro bumps (MBs) formed between the plurality of high-bandwidth DRAMs 3310, 3320, 3330, and 3340.

Here, the plurality of high-bandwidth DRAMs 3310, 3320, 3330 and 3340 may respectively transmit a temperature code TCODE and/or an error flag ERR_flag to the host die 3200. Thus, the host die 3200 transmits the temperature code TCODE and/or the error flag ERR_flag of a device adjacent to a device failing to generate a temperature code TCODE and/or an error flag ERR_flag among the plurality of high-bandwidth DRAMs 3310, 3320, 3330, and 3340.

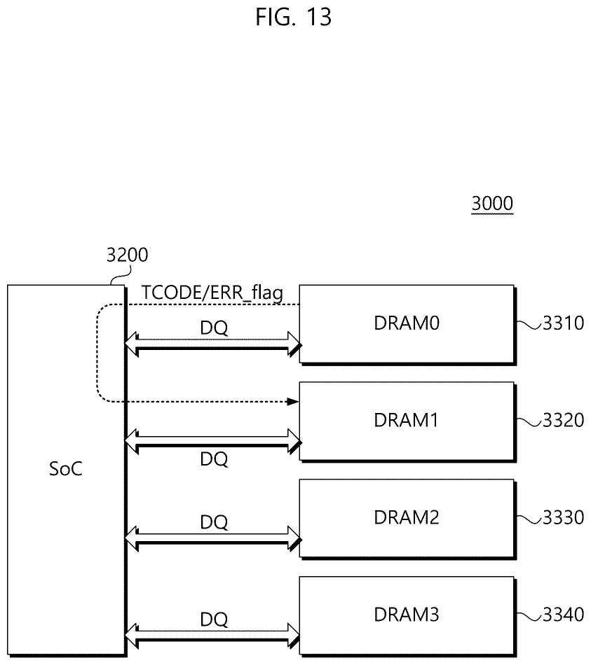

FIG. 13 illustrates a procedure for sharing a temperature code TCODE and/or an error flag ERR_flag in the memory system of FIG. 12. Referring to FIG. 13, a host die 3200 corresponding to a system on a chip SoC may transmit a temperature code TCODE and/or an error flag ERR_flag from at least one high-bandwidth DRAM such as 3310 to another high-bandwidth DRAM such as 3320.

The high-bandwidth DRAM 3320 need not perform a normal self-refresh operation due to an error in a circuit generating the temperature code TCODE and/or the error flag ERR_flag. Accordingly, the high-bandwidth DRAM 3320 may provide a message to the host die 3200 requesting a temperature code TCODE and/or an error flag ERR_flag of at least one adjacent high-bandwidth DRAM. The host die 3200 may provide a temperature code TCODE and/or an error flag ERR_flag generated in the high-bandwidth DRAM 3310 to the high-bandwidth DRAM 3320 in response to such a request of the high-bandwidth DRAM 3320. For example, the high-bandwidth DRAM 3320 may perform a self-refresh operation having a dynamically variable period by referring to the temperature code TCODE and/or the error flag ERR_flag generated by the high-bandwidth DRAM 3310.

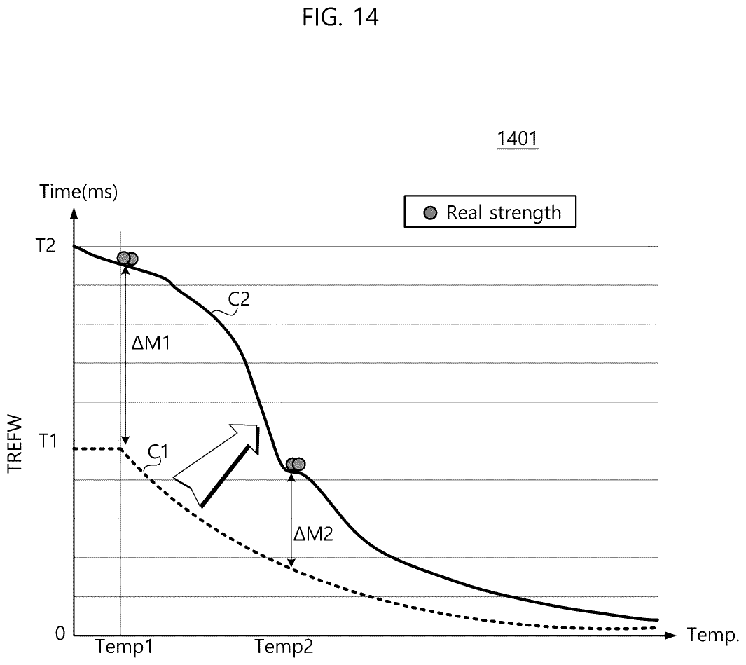

FIG. 14 shows a plot 1401 illustrating time versus temperature relationships for an embodiment of the present inventive concept. Referring to FIG. 14, when the self-refresh period is generated by correlating the error flag ERR_flag, and/or alternately the number of occurrences of the error flag nERR_flag, with the temperature code TCODE of an embodiment, the period of refresh clock TREFI may be increased until the error flag ERR_flag for each temperature occurs. In this case, a retention time that can be provided by a memory cell of the memory device 1000 may be maximally utilized and/or optimized with respect to power consumption, and thus a refresh period may be maximized. Circular dots in the illustrated graph represent actual strength or retention time of the memory device.

Curve C1 shows the refresh period time TREFW when the refresh period is set using substantially only the temperature code TCODE. On the other hand, the curve C2 shows the refresh period time TREFW of the present inventive concept, which generates a self-refresh period by correlating the error flag ERR_flag to the temperature code TCODE.

At the temperature Temp1, the refresh period time TREFW of the curve C2 to which the refresh period according to the present inventive concept may be increased by ‘ΔM1’ compared to the curve C1. This indicates that the cycle can be maximally increased while maintaining the integrity of the data of the self-refresh operation when the present inventive concept is applied.

Similarly, at the temperature Temp2, the refresh period time TREFW of the curve C2 to which the refresh period according to the embodiment of the present inventive concept may be increased by ‘ΔM2’ compared to the curve C1. As the temperature increases, the increase in the refresh period time TREFW gradually decreases compared to the curve C1, but it can be confirmed that the retention characteristics provided by the memory cells can be maximally utilized when the present inventive concept is applied.

The above are specific embodiments presently by way of example for practicing the present inventive concept, without limitation thereto. In addition to the above-described embodiments, those of ordinary skill in the pertinent art will appreciate that the scope and spirit of the present inventive concept include various design changes, modifications and/or combinations of embodiments. Moreover, it shall be understood that the present inventive concept includes techniques that can be readily modified and implemented based on these embodiments. Therefore, the scope of the present inventive concept should not be limited to the above-described embodiments, but should be defined by the claims to issue and equivalents thereof.

What is claimed is:

1. A self-refresh method of a semiconductor memory device, comprising:
generating a temperature code indicative of a temperature of the semiconductor memory device;
generating a first error flag indicative of any data errors in a memory area of the semiconductor memory device;
performing a first self-refresh operation for the memory area within a first refresh period based on the temperature code and the first error flag;
generating a second error flag indicative of any data errors in the memory area during the first self-refresh operation; and
performing a second self-refresh operation for the memory area within a second refresh period based on the temperature code and the second error flag,
wherein the second refresh period is longer than the first refresh period if the second error flag is indicative of no data errors in the memory area during the first self-refresh operation.

2. The method of claim 1, further comprising:
generating a first combination code by adding the temperature code and the first error flag; and
determining the first refresh period from the first combination code.

3. The method of claim 2, wherein when the first error flag does not occur, the first combination code is generated by adding a specific code value to the temperature code.

4. The method of claim 3, further comprising:
generating a second combination code by adding the temperature code and the second error flag; and
determining the second refresh period from the second combination code.

5. The method of claim 4, wherein when the first error flag and the second error flag do not occur, the second combination code is generated by adding twice the specific code value to the temperature code.

6. The method of claim 4, wherein when the first error flag does not occur and the second error flag does occur, the second combination code is generated by adding the specific code value to the temperature code.

7. The method of claim 1, wherein the first error flag or the second error flag indicates detection of a correctable error from data refreshed in the memory area.

8. The method of claim 1, wherein the first error flag or the second error flag includes a case where an uncorrectable error is detected from data refreshed in the memory area.

9. A semiconductor memory device, comprising:
a cell array including a plurality of memory cells;
an error correction circuit configured to generate an error flag during a self-refresh operation of the cell array;
a temperature sensor configured to detect an operation temperature of the semiconductor memory device and generate a temperature code;
a dynamic refresh period generator configured to generate a refresh period for the self-refresh operation by combining the temperature code and the error flag; and
a refresh controller performing a self-refresh operation for the cell array according to the refresh period,
wherein when the error flag is indicative of no data errors in the memory area during a first self-refresh operation, the dynamic refresh period generator is configured to generate an increased refresh period before a second self-refresh operation.

10. The device of claim 9, wherein the dynamic refresh period generator comprises:
a code adder generating a combined code by combining the temperature code and the error flag; and
a refresh period generator generating the refresh period according to the combination code.

11. The device of claim 10, wherein the code adder comprises:
a code converter generating an addition code corresponding to the error flag; and
a plurality of full adders configured to generate the combination code by adding the temperature code and the addition code.

12. The device of claim 11, wherein the code converter generates the addition code greater than ‘1’ when the error flag does not occur during the first self-refresh operation.

13. The device of claim 11, wherein the code converter generates the addition code corresponding to ‘0’ when the error flag is generated during the first self-refresh operation.

14. The device of claim 11, wherein the code converter includes a register for storing a generation history of the addition code.

15. The device of claim 10, wherein the code adder comprises:
a register counter counting the number of occurrences of the error flag;
a code converter generating an addition code corresponding to the number of occurrences of the error flag; and
a plurality of full adders configured to generate the combination code by adding the temperature code and the addition code.

16. The device of claim 9, wherein the dynamic refresh period generator generates a refresh period of a third self-refresh operation executed prior to the first self-refresh operation in the second self-refresh operation when the error flag occurs during the first refresh period.

17. The device of claim 9, wherein the dynamic refresh period generator sequentially performs a plurality of self-refresh operations and gradually increases the refresh period until the error flag occurs.

18. A self-refresh method of a semiconductor memory device, comprising:
generating a temperature code of the semiconductor memory device and a first error flag from a memory area to be refreshed;
counting a number of occurrences of the first error flag;
performing a first self-refresh operation for the memory area within a first refresh period based on the temperature code and the number of occurrences of the first error flag;
generating a second error flag by detecting an error in the memory area during the first self-refresh operation;
counting a number of occurrences of the second error flag; and
performing a second self-refresh operation for the memory area with a second refresh period based on the temperature code and the number of occurrences of the second error flag,
wherein when the number of occurrences of the second error flag is none, the second refresh period is longer than the first refresh period.

19. The method of claim 18, wherein when the number of occurrences of the second error flag is ‘1’ or more, the second refresh period is shorter than the first refresh period.

20. The method of claim 18, wherein when the number of occurrences of the second error flag is greater than ‘1’, the second refresh period increases in inverse proportion to the number of occurrences of the second error flag compared to the first refresh period.
